(19) United States
(12) Patent Application Publication
(10) Pub. No.: US 2009/0047791 A1
(43) Pub. Date: Feb. 19, 2009

(54) SEMICONDUCTOR ETCHING METHODS

(75) Inventors: David M. Dobuzinsky, New Windsor, NY (US); Johnathan E. Faltermeier, Delanson, NY (US); Munir D. Naeem, Poughkeepsie, NY (US); William C. Wille, Red Hook, NY (US); Richard S. Wise, Newburgh, NY (US)

Correspondence Address: HOFFMAN WARNICK LLC, 75 STATE ST, 14TH FL, ALBANY, NY, 12207, US

(73) Assignee: INTERNATIONAL BUSINESS MACHINES CORPORATION, Armonk, NY (US)

(21) Appl. No.: 11/839,681

(22) Filed: Aug. 16, 2007

(51) Int. Cl. H01L 21/302

(52) U.S. Cl. 438/705; 257/E21.039; 257/E21.034

(57) ABSTRACT

A method of etching semiconductor structures is disclosed. The method may include etching an SRAM portion of a semiconductor device, the method comprising: providing a silicon substrate layer, a nitride layer thereover, an optical dispersive layer over the nitride layer, and a silicon anti-reflective coating layer thereover; etching the silicon anti-reflective coating layer using an image layer; removing the image layer; etching the optical dispersive layer while removing the silicon anti-reflective coating layer; etching the optical dispersive layer and the nitride layer simultaneously; and etching the optical dispersive layer, the nitride layer, and the silicon substrate simultaneously.

### BACKGROUND

1. Technical Field

The disclosure relates generally to semiconductor fabrication, and more particularly, to methods of simultaneously etching different portions and layers of a semiconductor device.

2. Background Art

In the manufacture of Random Access Memory (RAM) structures, etching of a variety of films is quite challenging. RAM etch processes have to be tailored to meet selectivity requirements of doped poly-silicon, crystalline silicon, oxide, and silicon nitride, among others. One approach to this problem includes using additional masks such as oxide and poly-silicon to deal with the limited budget of photoresists. For smaller requirements (below 45 nanometers), electron-beam lithographic systems such as optical planarizing layers have to be employed to meet optical resolution requirements. When such layers are applied, etch process windows are limited even further and use of other masking materials (oxide and/or poly-silicon), also known as hard masks, becomes a major cost factor.

### SUMMARY

Methods of simultaneously etching layers of a semiconductor device are disclosed. A first aspect is directed to a method of etching a Static Random Access Memory (SRAM) portion of a semiconductor device, the method comprising: providing a silicon substrate layer, a nitride layer thereover, an optical dispersive layer over the nitride layer, and a silicon anti-reflective coating layer thereover; etching the silicon anti-reflective coating layer using an image layer; removing the image layer; etching the optical dispersive layer while removing the silicon anti-reflective coating layer; etching the optical dispersive layer and the nitride layer simultaneously; and etching the optical dispersive layer, the nitride layer, and the silicon substrate simultaneously.

A second aspect is directed to a method of etching a Static Random Access Memory (SRAM) portion of a semiconductor device, further comprising: providing a Dynamic Random Access Memory (DRAM) portion of a semiconductor device, the DRAM portion having a silicon substrate layer containing at least one filled deep trench lined with an oxide collar, a nitride layer thereover, an optical dispersive layer over the nitride layer, wherein at least one portion of the optical dispersive layer is in communication with the silicon substrate and the nitride layers, and a silicon anti-reflective coating layer thereover; etching the silicon anti-reflective coating layer using an image layer; removing the image layer; etching the optical dispersive layer while removing the silicon anti-reflective coating layer; etching the optical dispersive layer and the nitride layer simultaneously, such that the optical dispersive layer is no longer in communication with the silicon substrate; and etching the silicon substrate to expose at least one oxide collar.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIGS. 1A-2B show cross-sectional views of a semiconductor device as it proceeds through embodiments of methods of etching.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

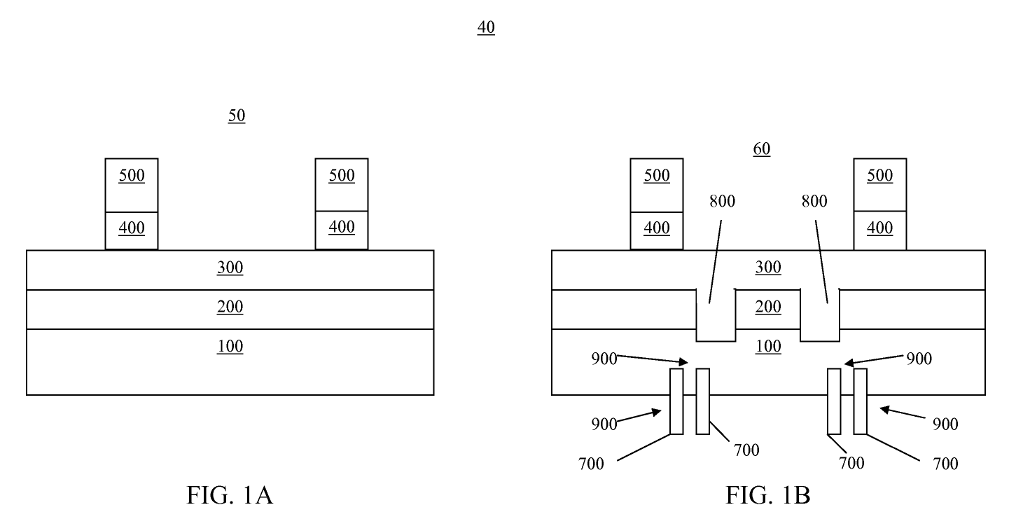

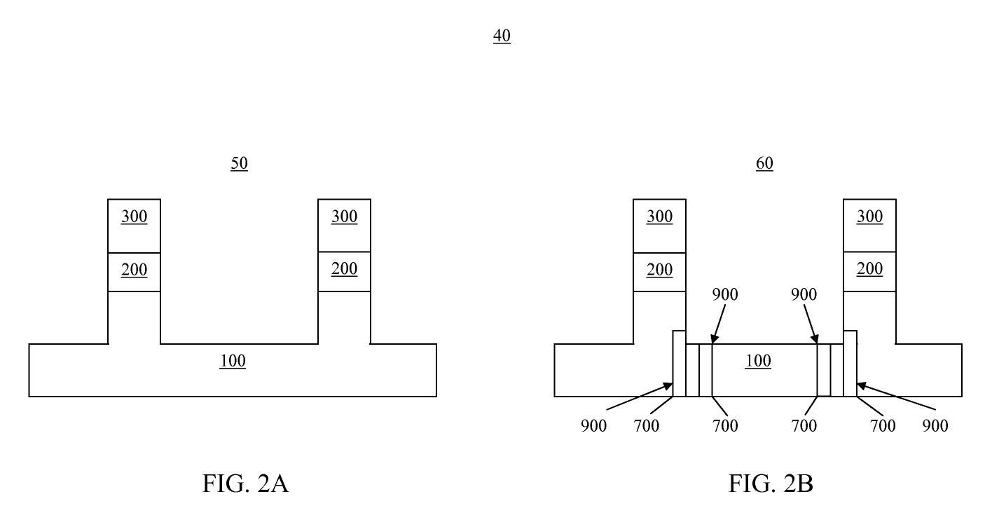

Referring to FIGS. 1A-1B and 2A-2B, embodiments of a method of etching are shown. It is noted that FIGS. 1A-1B and FIGS. 2A-2B can depict two portions of the same semiconductor device, or may be portions of distinct semiconductor devices.

FIG. 1A shows a cross-sectional view of a Static Random Access Memory (SRAM) portion 50 of a semiconductor device 40 after initial etching has occurred, according to the disclosure. It is noted that initial etching can be performed by any now known or later developed etching process appropriate for SRAM devices, such as photolithographic etching. At this stage in the etch process (post-initial etch), Silicon Anti-Reflective Coating (SiARC) layer 400 has been etched away, except for the portions residing underneath image layer 500. Image layer 500 acts as a mask to protect complete etching of SiARC layer 400 during initial etch. SRAM portion 50 of semiconductor device 40 has a semiconductor substrate 100 and a nitride layer 200 on semiconductor substrate 100. On top of nitride layer 200 is located optical dispersive layer (ODL) 300. ODL 300 acts to refract portions of light waves that pass through it, so as to provide greater accuracy in photolithography processes. Above ODL 300 is located the remaining SiARC layer 400 and remaining image layer 500 thereover. As shown, SiARC layer 400 and image layer 500 have been partially etched away.

FIG. 1B shows a cross-sectional view of a Dynamic Random Access Memory (DRAM) portion 60 of a semiconductor device 40 after initial etching has occurred. It is noted that initial etching can be performed by any now known or later developed etching process appropriate for DRAM devices, such as photolithographic etching. DRAM portion 60 of semiconductor device 40 has a semiconductor substrate 100 and a nitride layer 200 on semiconductor substrate 100. Within semiconductor substrate 100 are located filled deep trenches 900. These deep trenches 900 are holes previously drilled and filled in the silicon substrate that are capable of storing charge. Trenches 900, are lined by oxide collars 700. On top of nitride layer 200 is located optical dispersive layer (ODL) 300. ODL 300 is also connected to semiconductor substrate 100 via channels 800 through nitride layer 200. Above ODL 300 is located SiARC layer 400 and an image layer 500 thereover. During initial etching, silicon anti-reflective coating (SiARC) layer 400 is etched away, except for the portions residing underneath image layer 500. Image layer 500 acts as a mask to protect complete etching of SiARC layer 400 during initial etching.

FIG. 2A shows a cross-sectional view of an SRAM portion 50 of a semiconductor device 40 after etching, according to the disclosure. It is noted that FIG. 2A represents the same SRAM portion 50 as depicted in FIG. 1A, at a different stage in the etching process. After the initial etching step shown in FIG. 1A, image layer 500 is removed. The initial etching step may be performed using any combination of chemistry and pattern transfer commonly used in the semiconductor industry. ODL 300 is then etched while removing SiARC layer 400 (FIG. 1A). This provides for selectivity to ODL 300. After SiARC layer 400 (FIG. 1A) is removed, remaining ODL 300 and nitride layer 200 are simultaneously etched. The above etching steps may be performed using any chemistry commonly used in the semiconductor industry. Finally, ODL 300, nitride layer 200, and silicon substrate 100 are all etched simultaneously to leave a thin layer of ODL 300 atop the nitride layer 200. This process may involve using a combination of chemistry and etch timing to control the silicon etch.

FIG. 2B shows a cross-sectional view of a DRAM portion 60 of a semiconductor device 40 after etching, according to the disclosure. It is noted that FIG. 2B represents the same DRAM portion 60 as depicted in FIG. 1B, at a different stage in the etching process. After the initial etching step shown in FIG. 1B, image layer 500 is removed. The initial etching step may be performed using any combination of chemistry and pattern transfer commonly used in the semiconductor industry. ODL 300 is then etched while removing SiARC layer 400 (FIG. 1B). This provides for selectivity to the ODL 300. After SiARC layer 400 (FIG. 1B) is removed and all portions of the ODL 300 located within channels 800 (FIG. 1B) have been etched away, remaining ODL 300 and nitride layer 200 are simultaneously etched. Next, ODL 300, nitride layer 200, and silicon substrate 100 are all etched simultaneously to leave a thin layer of ODL 300 atop the nitride layer 200. Oxide collars 700 reside within the silicon substrate 200, and line deep trenches 900. These deep trenches 900 are holes previously drilled in the silicon substrate that are capable of storing charge. Initially, due to commonly known chemistry and controlled timing techniques, deep trenches 900, and the oxide collars 700 lining such trenches 900 are not initially exposed. However, after final etching step, FIG. 2B shows exposed oxide collars 700.

The final etching step shown in FIG. 2B may provide certain chemistry including TetraFlouroMethane (CF₄), OctaFlouroCyclobutane (C₄F₈), and Nitrogen gas (N₂), a flow rate in the range of approximately 30-70 standard cubic centimeters CF₄, approximately 5-30 standard cubic centimeters C₄F₈, and approximately 30-70 standard cubic centimeters N₂. The etch environment may be provided at a pressure in the range of approximately 10-100 mili-Torr, in a reactor with a source power in the range of approximately 600-1000 Watts and a bias power of approximately 100-300 Watts. These conditions prevent over-etching of ODL 300 and nitride layer 200 while effectively etching oxide collars 700. The above-discussed chemistry and conditions allow for selectivity in etching within deep trenches.

The foregoing description of various aspects of the disclosure has been presented for purposes of illustration and description. It is not intended to be exhaustive or to limit the disclosure to the precise form disclosed, and obviously, many modifications and variations are possible. Such modifications and variations that may be apparent to a person skilled in the art are intended to be included within the scope of the disclosure as defined by the accompanying claims.

What is claimed is:

1. A method of etching an SRAM portion of a semiconductor device, the method comprising:
providing a silicon substrate layer, a nitride layer thereover, an optical dispersive layer over the nitride layer, and a silicon anti-reflective coating layer thereover;
etching the silicon anti-reflective coating layer using an image layer;
removing the image layer;
etching the optical dispersive layer while removing the silicon anti-reflective coating layer;
etching the optical dispersive layer and the nitride layer simultaneously; and
etching the optical dispersive layer, the nitride layer, and the silicon substrate simultaneously.

2. The method of claim 1, wherein the silicon substrate is formed of a poly-silicon.

3. The method of claim 1, wherein the silicon substrate is formed of a single-crystal silicon.

4. A method of etching a DRAM portion of a semiconductor device, the method comprising:
providing a silicon substrate layer containing at least one deep trench lined with an oxide collar, a nitride layer thereover, an optical dispersive layer over the nitride layer, wherein at least one portion of the optical dispersive layer is in communication with the silicon substrate and the nitride layers, and a silicon anti-reflective coating layer thereover;
etching the silicon anti-reflective coating layer using an image layer;
removing the image layer;
etching the optical dispersive layer while removing the silicon anti-reflective coating layer;
etching the optical dispersive layer and the nitride layer simultaneously, such that the optical dispersive layer is no longer in communication with the silicon substrate; and
etching the silicon substrate to expose at least one oxide collar.

5. The method of claim 4, further comprising:
providing an SRAM portion of the semiconductor device, the SRAM portion having the silicon substrate layer, the nitride layer thereover, the optical dispersive layer over the nitride layer, and the silicon anti-reflective coating layer thereover;
etching the silicon anti-reflective coating layer using the image layer;
removing the image layer;
etching the optical dispersive layer while removing the silicon anti-reflective coating layer;
etching the optical dispersive layer and the nitride layer simultaneously; and
etching the optical dispersive layer, the nitride layer, and the silicon substrate simultaneously.

6. The method of claim 4, wherein the silicon substrate is formed of one of a single-crystal silicon and a poly-silicon.
